(19) United States
(12) Patent Application Publication
(10) Pub. No.: US 2009/0042336 A1
(43) Pub. Date: Feb. 12, 2009

(54) Fabrication method of an organic substrate having embedded active-chips

(76) Inventors: Kyung-Wook Paik, Daejeon (KR); Ho-Young Son, Daejeon (KR)

Correspondence Address: THE NATH LAW GROUP, 112 South West Street, Alexandria, VA, 22314, US

(21) Appl. No.: 12/010,894

(22) Filed: Jan. 30, 2008

(30) Foreign Application Priority Data
Aug. 6, 2007 (KR) 10-2007-0078457

(51) Int. Cl. H01L 21/60

(52) U.S. Cl. 438/107; 257/E21.512

(57) ABSTRACT

The fabrication method of an organic substrate having embedded active-chips such as semiconductor chips is disclosed. The present invention previously applies the conductive adhesives in a wafer state, makes them in a B-stage state, obtains individual semiconductor chips through dicing, and positions the individual semiconductor chips previously applied with the conductive adhesives in the cavities, making it possible to simultaneously obtain an electrical connection and a physical adhesion of the substrate and the semiconductor chips by means of a method of applying heat and pressure and stack the copper clad laminates on the upper portion of the substrate to which the semiconductor chips are connected. The present invention has advantages in processes such as a lead-free process, an environmental-friendly fluxless process, a low temperature process, ultra-fine pitch applications, etc., by mounting the active-chips through the flip chip interconnection using the non-solder bumps and the conductive adhesives.

### BACKGROUND OF THE INVENTION

This application claims priority to Korean Patent Application No. 2007-0078457 filed on Aug. 6, 2007, in the Korean Intellectual Property Office, the entire contents of which are hereby incorporated by reference.

1. Field of the Invention

The present invention relates to a fabrication method of an organic substrate having embedded active-chips such as semiconductor chips.

2. Description of the Related Art

Electronic packaging technologies are a very important technology that determines the performance, size, price, and reliability of electronic products. The importance of the electronic packaging technologies has been highly recognized due to the recent trend of the high electrical performance and miniaturization of the electronic products. Among such electronic packaging technologies, a system in package (SIP) technology is to implement one system in a package. For this purpose, a silicon through-hole technology, a chip stacking technology, a technology of embedding active devices (active-chips) and passive components in a substrate, etc., are needed. Among them, the embedding technology of active devices such as IC chips and passive components such as capacitors, resistors, and inductors in an organic substrate, can reduce the size and thickness of the package, reduce noise, delay, etc., by reducing parasitic components, and improve electrical performance and high frequency characteristics by shortening the interconnection length. FIGS. 1 and 2 are views showing examples of a conventional package where active-chips and passive components are formed on the organic substrate and an embedded package where active-chips and passive components are mounted in the organic substrate.

The embedding technology of the active-chips such as the semiconductor chips in the organic substrate has widely been studied and developed in Motolora, Embera, etc. Generally, after dented cavities formed on the top surfaces of an organic substrate which its several. copper clad laminated (CCL) layers were laminated one another and the chips are mounted in these cavities, the circumference of the chip is molded with epoxy and a copper clad laminate is stacked on the top surface of the layers to finally manufacture a printed circuit board (PCB).

At this time, there are several methods of mounting the semiconductor chips in the organic substrate and then connecting them. A wire bonding method, an electroplating method, a flip chip interconnection method using solder bumps, etc., are generally used. Among others, in the case of the wire bonding method (FIG. 3), it limits the number of I/Os in the chip and it is difficult to implement a light, slim, short, and small structure due to a wire shape and in the case of the electroplating method (FIG. 4), complex processes such as a seed layer deposition process, a thick film photo resist (PR) coating, and an exposure process, a plating process, an etching process, etc. are needed. Even in the case of the flip chip interconnection method using the solder bumps (FIG. 5), it is difficult to embed the IC chips in the substrate due to complex processes, that is, there should be performed a solder flux coating process, an alignment process of chip and substrate, a solder reflow process, a flux cleaning process, an underfill coating process, and a curing process, etc. In particular, it is very difficult to dispense underfill materials into the inside of the layer having the dented cavities and it should be subject to several processes which thus increase the cost.

On the other hand, the importance of the flip chip connection technology using non-solder bumps and conductive adhesives is highly recognized due to a simple process, a lead-free process, an environmental-friendly fluxless process, a low temperature process, ultra-fine pitch applications, etc., as compared to the flip chip interconnection technology using the solder bumps. The flip chip interconnection technology has been applied to an organic substrate, a rigid board such as glass, etc., and a flexible substrate, and the like in various forms such as a chip-on-board (COB), a chip-on-glass (COG), a chip-on-flex (COF), and the like. Therefore, the use of such adhesives for both of the interconnection of the IC chips for a display such as an LCD, a PDP, etc., and the flip chip connection using the IC chips for the semiconductor in recent times shows a tendency to increase.

The conductive adhesives used for the connection of chip and substrate are divided into anisotropic conductive adhesives (ACA) and non-conductive adhesives (NCA) according to whether or not they comprise conductive balls. The conductive adhesives are divided into anisotropic conductive film (ACF) and non-conductive film (NCF) in a film form and anisotropic conductive paste (ACP) and non-conductive paste (NCP) in a paste form, according to their form.

As the interconnection method of the active-chips (IC chips) in the printed circuit board (PCB), etc., having the embedded passive components and active-chips, there is the wire bonding method that lifts up the surfaces of the chips formed with a metal electrode and performs the wire bonding of the chips or the flip chip interconnection method that reversely turns over the surfaces of the chips formed with a metal electrode and then uses the solder bumps. However, until now it has been no attempt to fabricate an organic substrate with embedded active-chips using the conductive adhesives.

Although the interconnection method using the conductive adhesives has advantages in a process over the wire bonding method or the flip chip connection method using the solder bump, there are partial cavities on the area where the IC chips will be mounted. Therefore, since it is very difficult to perform the process of previously prelaminating the conductive adhesives to such an uneven structure and removing releasing film, it is not easy to achieve the interconnection using the conductive adhesives to the printed circuit board having the embedded active-chips.

The present inventors previously proposed a method that forms low-cost non-solder flip chip bumps at a wafer level, applies the anisotropic conductive adhesives thereto, dices them into individually package chips, and connects the individually packaged chips to the substrate (for example, Korean Patent Registration No. 10-0361640).

In order to solve the problems in the processes caused when mounting the active-chips in the substrate using the conductive adhesives, there is provided a new method of embedding the active-chips using the packaged individual chips.

### SUMMARY OF THE INVENTION

Accordingly, in order to embed active-chips in an organic substrate while having advantages in a process in a flip chip interconnection using conductive adhesives, the object of the present invention is to solve the problems in processes such as chip-size cutting of conductive adhesives, individual prelamination of chip-size conductive adhesives, and releasing film removal, etc.

The fabrication method of an organic substrate having embedded active-chips comprises the steps of: (a) stacking the second copper clad laminate formed with copper wirings, vias, and cavities on the top surface of the first copper clad laminate formed with the copper wirings or the copper wirings and the vias; (b) applying anisotropic conductive adhesives or non-conductive adhesives to the top surface of a semiconductor wafer and then positioning active-chips (IC chips) diced into individual chips inside the cavities of the second copper clad laminate and connecting the copper wirings of the first copper clad laminate to a flip chip by applying heat and pressure; and (c) stacking the third copper clad laminate formed with the copper wirings or the copper wirings and the vias on the top surface of the second copper clad laminate to which the active-chips are connected.

The active-chips of the step (b) are fabricated comprising the steps of: forming non-solder bumps on the I/Os of each chip on a thin wafer of 200 μm or less using a gold wire bonding method or a nickel and gold plating method; applying the anisotropic conductive adhesives or the non-conductive adhesives in a B-stage state to the top surface of the wafer formed with the non-solder bumps; and dicing the wafer applied with the anisotropic conductive adhesives or the non-conductive adhesives into individual active-chips.

In addition, after the step (b), the organic substrate having the embedded active-chips with the number of desired layers can be fabricated by repeating the same method as the step (b) by forming the cavities at different positions from the cavities formed on the copper clad laminate to which the active-chips are connected and stacking the copper clad laminates formed with the copper wirings and the vias.

The anisotropic conductive adhesives or the non-conductive adhesives may be of a film form or a paste form.

Preferably, the flip chip interconnection in the step (b) is made by applying heat of 150 to 200° C. and pressure of 20 to 100 psi for 10 to 20 seconds. Preferably, the material of the organic substrate is BT, FR04 or FR05, and so on.

With the present invention, an integration technology for embedded active-chips based on a wafer level package process as well as a printed circuit board design, and fabricating technology for embedded active-chips and passivae components and a fabricating technology for a wafer level package in various forms to which conductive adhesives are applied, etc., can primarily be established. In the case of the printed circuit board for the embedded active-chips developed according to the present invention, it can be expected that the active-chips (semiconductor-chips) are embedded in the substrate so that the thickness of the package decreases and the interconnection length becomes short so that the reliability of the package is enhanced. Meanwhile, the present invention can be used in a system in package (SIP) of information and communication mobile product based on the printed circuit board including the embedded active-chips and passive components by using the printed circuit board fabricating technology for the embedded active-chips and passive components. This can significantly contribute to the provision of next generation core package components for higher speed Tbps-grade information and communication systems capable of processing higher capacity of information than possible in the prior art through the use of new IC-embdding technology.

### BRIEF DESCRIPTION OF THE DRAWINGS

The objects, features, and advantages of preferred embodiments of the present invention will be more fully described in the following detailed description, taken in conjunction with the accompanying drawings. In the drawings:

FIG. 1 is a view showing an example of a conventional package where passive components and active-chips are formed on an organic substrate;

FIG. 2 is a view showing an example of a package where passive components and active-chips are embedded in an organic substrate;

FIG. 3 is a view showing an example of a printed circuit board (PCB) having embedded active-chips using wire bonding technology;

FIG. 4 is a view showing an example of a printed circuit board (PCB) having embedded active-chips using an electroplating method;

FIG. 5 a view showing an example of a printed circuit board (PCB) having embedded active-chips using a flip chip technology using solder bumps;

FIG. 6 is one example showing a fabricating method of semiconductor chips using conductive adhesives; and

FIG. 7 is a view showing an example of a method of embedding semiconductor chips (active-chips) in an organic substrate according to the present invention.

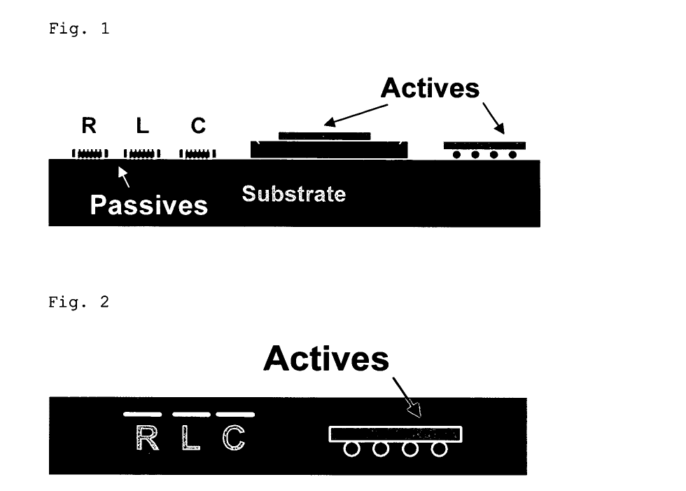

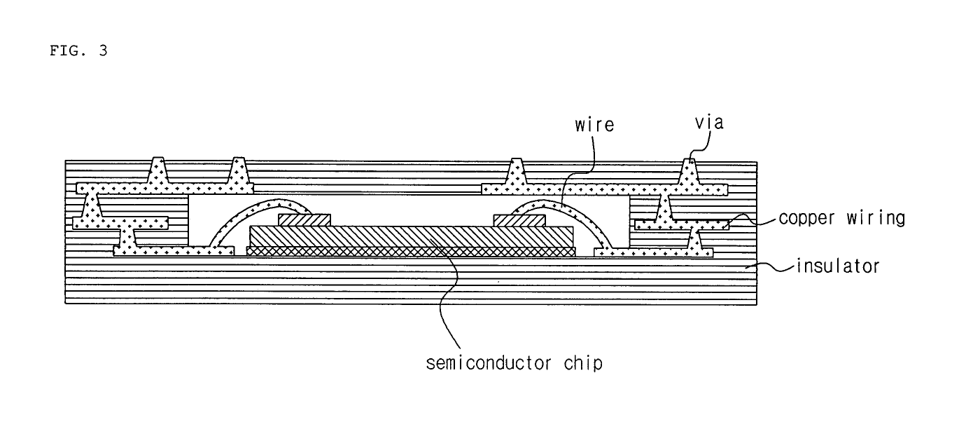

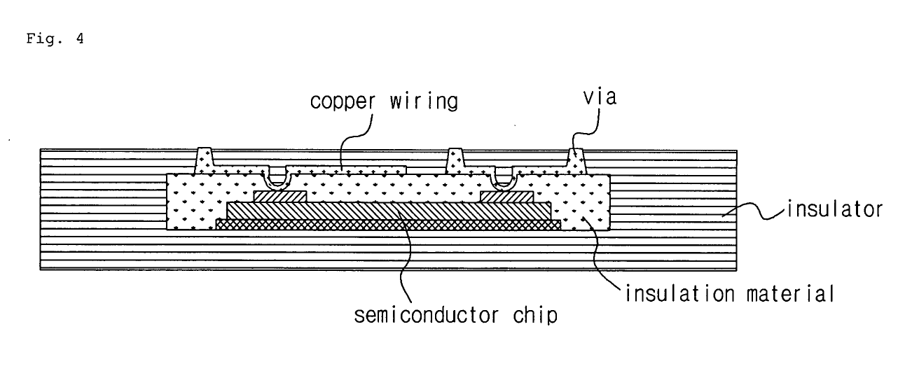

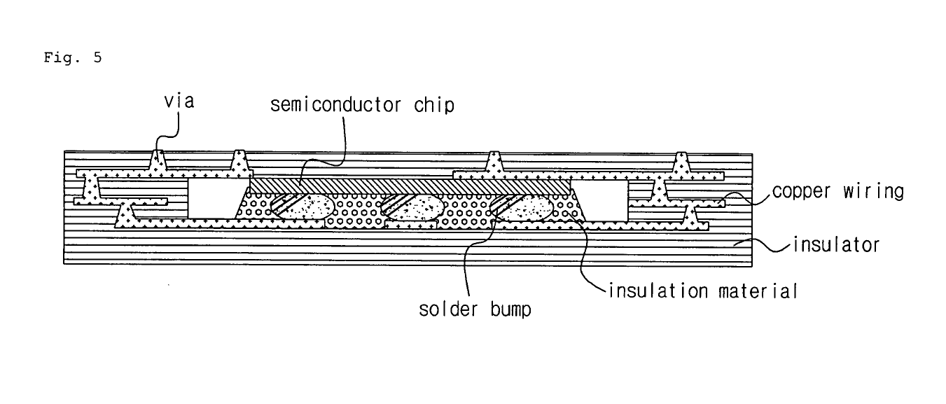

### DETAILED DESCRIPTION OF THE INVENTION

Hereinafter, the fabrication method of an organic substrate having embedded active-chips of the present invention will be described in detail with reference to the accompanying drawings. The following drawings are provided, by way of example, to sufficiently transfer the idea of the present invention to those skilled in the art. Therefore, the present invention is not limited to the following drawings and can be embodied in other forms. In addition, the same reference numerals are used to refer to the same parts throughout the specification.

At this time, unless the terms and scientific terminologies used in the specification are defined, they have meanings understood by those skilled in the art. The following description of known functions and configurations will be omitted so as not to obscure the subject of the present invention with unnecessary detail.

The present invention is a method that embed active-chips in a printed circuit board using a flip chip interconnection method using conductive adhesives.

The fabrication method of an organic substrate having active-chips of the present invention comprises the steps of: (a) stacking the second copper clad laminate formed with copper wirings, vias, and cavities on the top surface of the first copper clad laminate formed with the copper wirings or the copper wirings and the vias; (b) applying anisotropic conductive adhesives or non-conductive adhesives to the top surface of a semiconductor wafer and then positioning semiconductor chips (active-chips) diced into individual chips inside the cavities of the second copper clad laminate and connecting the copper wirings of the first copper clad laminate to a flip chip by applying heat and pressure; and (c) stacking the third copper clad laminate formed with the copper wirings or the copper wirings and the vias on the top surface of the second copper clad laminate to which the semiconductor chips are connected.

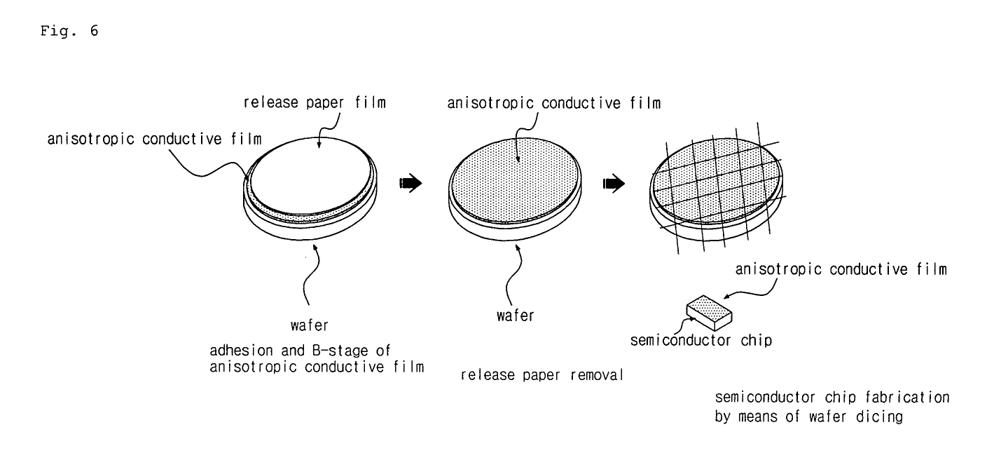

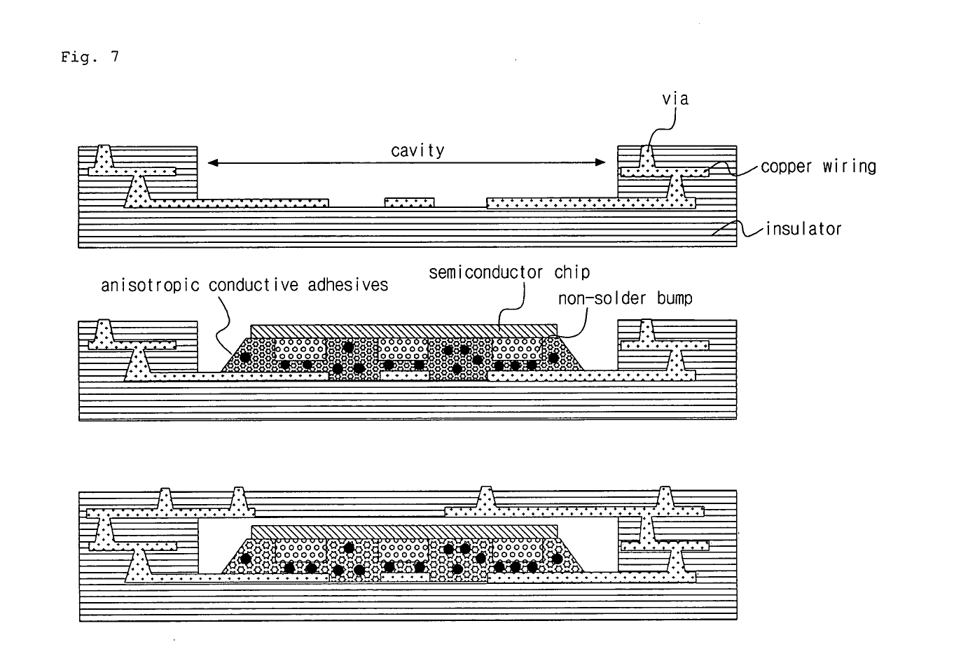

This invention differentiate from the conventional processes of applying conductive adhesives to an top surface of a substrate having prominences and depressions by the existence of cavities for embedding semiconductor chips (active-chips) in an organic substrate and removing releasing film. That is, as shown in FIG. 6, the method according to the present invention previously applies the conductive adhesives in a wafer state, makes them in a B-stage state, obtains individual semiconductor chips through dicing, and positions the individual semiconductor chips previously applied with the conductive adhesives in the cavities, making it possible to simultaneously obtain an electrical connection and a physical adhesion of the substrate and the semiconductor chips by applying heat and pressure.

Accordingly, the present invention can embed the semiconductor chips inside of the substrate using the conductive adhesives without having the problems in the process such as prelaminating, chip-size cutting of the conductive adhesives, and the releasing film removal, etc. and can also embed the semiconductor chips in the substrate having cavities such as prominences and depressions using a simple process which applies heat and pressure.

A printed circuit board (PCB) consists of several PCB layers. Each PCB layer is lightly coated with copper layers (referred to as a copper clad laminate (CCL)) for metal wirings on/beneath a typical isolation substrate (core, organic substrate) material. They form an interlayer connection using copper layer etching and micro via technologies.

As shown in FIG. 7, in order to embed the semiconductor chips (active-chips) in the PCB substrate, one or two copper clad laminates are first stacked and the copper wirings should be formed through an etching process on the area where the chips will be mounted. At this time, the cavities should be fabricated in the copper clad laminate on the area where the semiconductor chips are disposed. In other words, the process of previously processing the cavities by means of a mechanical processing method or a laser processing method, etc., and forming the copper wirings conformed to the metal terminals arrangement of the semiconductor chips should be performed firstly so that the chips can be connected to the copper clad laminates on the top surface of the PCB substrate.

In addition, after the copper clad laminates formed with the cavities are stacked, the connection can be made by positioning the semiconductor chips inside of the cavities, and then, after the semiconductor chips are connected on the copper clad laminates formed with only the copper wirings, not formed with the cavities, a method of stacking the copper clad laminates formed with the cavities to allow the semiconductor chips to be positioned inside the cavities can be performed.

The stack of the copper clad laminates is made by means of a lamination method that generally applies high heat and pressure.

More concretely reviewing the fabrication method of the semiconductor chips of the step (b) with reference to FIG. 6, the semiconductor chips of the step (b) are fabricated comprising the steps of: forming non-solder bumps on the I/Os of each chip on a thin wafer of 200 μm or less using a gold wire bonding method or a nickel and gold plating method; applying the anisotropic conductive adhesives or the non-conductive adhesives in a B-stage state to the top surface of the wafer formed with the non-solder bumps; and dicing the wafer applied with the anisotropic conductive adhesives or the non-conductive adhesives into individual semiconductor chips.

Since the thickness of the wafer determines the thickness of the completed individual semiconductor chips, the thickness thereof is preferably 200 μm or less in order to prevent an unnecessary increase in thickness and to obtain greater flexibility, and more preferably, 100 μm or less. In addition, the thickness of the wafer is preferably 1 μm or higher in order to prevent changes in the electrical characteristics of the devices due to the doping of impurities existing near the surface of the wafer and to facilitate the physical handling thereof.

Each chip individualed from a thinned wafer as above have metal pad I/Os such as Al and Cu by metallization process, wherein after the metal bumps formed on the metal pad I/Os using a gold or copper bonding wire or the non-solder bumps formed using a metal plating method and the conductive adhesives are applied.

The conductive adhesives may be anisotropic conductive adhesives or non-conductive adhesives and the anisotropic conductive adhesives may be of a film form or a paste form and the non-conductive adhesives may be of a film form or a paste form.

When the conductive adhesives in the paste form are applied to the front surface of the wafer formed with the non-solder bumps, it can be applied by means of a spray method, a doctor blade method, a meniscus method, etc., and in the case of the conductive adhesives in the film form, it can be applied by means of a lamination method.

At this time, the applied conductive adhesives are in the B-stage state where resin forming the conductive adhesives is cured to about 50% by applying heat or heat and pressure simulataneously. The conductive adhesives of such a B-stage state can be completely cured by applying heat of 150 to 200° C. and pressure of 20 to 100 psi for 10 to 20 seconds.

The wafer applied with anisotropic conductive adhesives or the non-conductive adhesives is diced into the individual semiconductor chips by means of a wafer dicing machine.

The flip chip interconnection of the step (b) is achieved with the copper of the first copper clad laminate by positioning the individual semiconductor chips in the cavities in the second copper clad laminate and applying heat of 150 to 200° C. and pressure of 20 to 100 psi for 10 to 20 seconds.

At this time, a plurality of cavities are formed in a single copper clad laminate so that the semiconductor chips are mounted inside of an organic substrate with cavities. Prior to the step (c), the cavities formed in the copper clad laminates stacked in several layers by repeating the same method as the step (b) by forming the cavities at different positions from the cavities formed in the copper clad laminates to which the semiconductor chips are connected and stacking the copper clad laminates formed with the copper wirings and the vias so that the semiconductor chips can be embedded.

After the stack of the copper clad laminates to which the semiconductor chips are connected are completed, the step (c) is performed, wherein the semiconductor chips are mounted into the inside of the substrate by stacking the copper clad laminates formed with the copper wirings or the copper wirings and the vias on the upper portions of the copper clad laminates to which the semiconductor chips are connected.

The material of the insulation substrate (organic substrate) of the copper clad laminate is BT, FR04 or FR05.

The fabrication method of the organic substrate having the embedded active-chips of the present invention as described above is to finally fabricate the organic substrate having the embedded active-chips by applying the conductive adhesives in a wafer state, positioning the individual semiconductor chips obtained by dicing in the cavities to be able to make the flip chip connection by applying only heat and pressure, and stacking the copper clad laminates on the upper portion thereof. Therefore, the fabrication method of the organic substrate having the embedded active-chips of the present invention: does not need the processes such as chip-size cutting conductive adhesives and individual prelamination of chip-size conductive adhesives, the releasing film removal, and so on.; can simultaneously obtain the electrical connection and the mechanical adhesion of the substrate and the semiconductor chips by means of a simple process of applying heat and pressure; does not require to fill the inside of the cavities where the chips are positioned with epoxy, etc.; and can facilitate the flip chip alignment of the semiconductor chips and the copper wirings of the substrate by means of the transparency of the conductive adhesives in the B-stage state.

In addition, since the present invention is a form of the flip chip interconnection, the number of I/Os and shape of the semiconductor chips are not limited and a light, slim, short, and small substrate can be obtained by reducing the thickness in the wafer state and applying the conductive adhesives and dicing them to make the flip chip interconnection of the semiconductor chips and the copper wirings of the substrate. The present invention has advantages in processes such as a lead-free process, an environmental-friendly fluxless process, a low temperature process, ultra-fine pitch applications, etc., by using the non-solder bumps and the conductive adhesives.

What is claimed is:

1. The fabrication method of an organic substrate having embedded active-chips comprising the steps of:
(a) stacking the second copper clad laminate formed with copper wirings, vias, and cavities on the top surface of the first copper clad laminate formed with the copper wirings or the copper wirings and the vias;
(b) applying anisotropic conductive adhesives or non-conductive adhesives to the front side of a semiconductor wafer and then positioning semiconductor chips diced into individual chips inside the cavities of the second copper clad laminate and connecting the copper wirings of the first copper clad laminate to a flip chip by applying heat and pressure; and
(c) stacking the third copper clad laminate formed with the copper wirings or the copper wirings and the vias on the top surface of the second copper clad laminate to which the semiconductor chips are connected.

2. The method according to claim 1, wherein the semiconductor chips of the step (b) are fabricated comprising the steps of:
forming non-solder bumps on the I/Os of each chip on a light and slim wafer of 200 μm or less using a gold wire bonding method or a nickel/gold plating method;
applying the anisotropic conductive adhesives or the non-conductive adhesives in a B-stage state to the upper portion of the wafer formed with the non-solder bumps; and
dicing the wafer applied with the anisotropic conductive adhesives or the non-conductive adhesives into individual semiconductor chips.

3. The method according to claim 1, wherein after the step (b), the organic substrate having the embedded active-chips is fabricated by repeating the same method as the step (b) by forming the cavities at different positions from the cavities formed on the copper clad laminate to which the semiconductor chips are connected and stacking the copper clad laminates formed with the copper wirings and the vias.

4. The method according to claim 2, wherein the anisotropic conductive adhesives or the non-conductive adhesives is a film form or a paste form.

5. The method according to claim 1, wherein the flip chip connection in the step (b) is performed by applying heat of 150 to 200° C. and pressure of 20 to 100 psi for 10 to 20 seconds.

6. The method according to claim 1, wherein the material of the organic substrate is BT, FR04 or FR05.
